(19) United States
(12) Patent Application Publication
(10) Pub. No.: US 2002/0093384 A1
(43) Pub. Date: Jul. 18, 2002

(54) High-directivity and adjusable directional couplers and method therefor

(76) Inventors: Donnie W. Woods, Thousand Oaks, CA (US); Charles D. Pitcher, Thousand Oaks, CA (US)

Correspondence Address: BLAKELY SOKOLOFF TAYLOR & ZAFMAN, 12400 WILSHIRE BOULEVARD, SEVENTH FLOOR, LOS ANGELES, CA, 90025, US

(21) Appl. No.: 09/759,653

(22) Filed: Jan. 12, 2001

(51) Int. Cl. H01P 5/18; H03L 7/08

(52) U.S. Cl. 331/25; 333/111; 333/116; 455/260; 455/319

(57) ABSTRACT

A directional coupler characterized as having improved directivity. The directional coupler and methodology uses enhanced destructive interference to reduce the leakage at the output port of a signal incident at the coupled port of the coupler thereby giving the coupler improved directivity. The directional coupler creates this enhanced destructive interference by the introduction of impedance discontinuities in the coupled transmission lines. The impedance discontinuity in the coupled transmission lines can take on many forms, such as recesses at the coupling sides of the coupled transmission lines, protrusions at the non-coupling sides of the coupled transmission lines, or both. Another directional coupler is capable of being tuned for different coupling levels. This coupler comprises adjacent conductors between the coupled transmission lines that are connected, as required, to the coupled lines to change the coupling level.

### FIELD OF THE INVENTION

This invention relates generally to radio frequency (RF) and microwave circuits, and in particular, to a directional coupler having relatively high-directivity due to discontinuities that cause destructive interference of an incident signal at the coupled port of the coupler and to a directional coupler with an adjustable coupling level.

### BACKGROUND OF THE INVENTION

Directional couplers are extensively used in the radio frequency (RF) and microwave/millimeterwave field. They are typically used to sample a signal for further processing and/or control. For example, directional couplers are used in the frequency control of dielectric resonator oscillators (DROs). In this regard, a directional coupler is placed at the output of a DRO to provide a sample of the DRO's output signal. The sampled signal is applied to a phase detector for phase comparison with a highly frequency-stable crystal oscillator. The phase detector generates a phase error signal, which is subsequently filtered to produce a frequency control signal for the DRO. The frequency control signal causes the DRO to produce an output signal whose frequency stability is tied to that of the crystal oscillator.

A directional coupler typically comprises four ports: an input port, an output port, a coupled port, and an isolated port. An incident signal is applied to the input port, and a first portion of the incident signal is produced at the output port and a second portion of the incident signal is produced at the coupled port. For example, if the coupling of a directional coupler is 10 dB, then one-tenth (1/10) of the incident signal is produced at the coupled port, and nine-tenths (9/10) of the incident signal is produced at the output port. In an ideal coupler, which has infinite directivity, none of the incident signal is produced at the isolated port.

However, most if not all directional couplers do not perform the same as ideal couplers. Accordingly, they have a finite directivity. Therefore, some of the incident signal applied to the input port ends up at the isolated port. Typically, directional couplers have a directivity value that produces a signal level at the isolated port that is approximately 10 dB lower in amplitude than the coupling level. Taking the same example above, a typical 10 dB coupler will have a directivity of approximately 20 dB. That is, there is a signal generated at the isolated port that is 20 dB below the incident signal at the input port. Generally, for an incident signal at the input port, this is not a significant problem (other than a small contribution to the insertion loss of the coupler) since the signal generated at the isolated port is simply dissipated through a load typically connected to the isolated port.

Relatively low directivity becomes a problem when there is an incident signal at the coupled port. This is because for an incident signal at the coupled port, the output port now becomes the “isolated port.” Thus, if a directional coupler has a relatively low directivity, an incident signal present at the coupled port ends up at the output port. In DRO applications, the coupled port of a directional coupler is coupled to the phase detector circuit for supplying a portion of the DRO RF/microwave/millimeterwave signal to the phase detector circuit. Thus, harmonics from the reference oscillator, reflected DRO signals with reference harmonic sidebands, and other spurious signals generated by the phase detector circuit may end up as incident signals at the coupled port. Since a directional coupler has a frequency response similar to a bandpass filter, the low frequency reference oscillator harmonics and spurious signals will be well attenuated on the way to the output port of the coupler. In a similar manner, reference oscillator harmonics and spurious signals beyond the passband of the coupler will also be attenuated. Only the directivity of the directional coupler will attenuate any signals within the passband of the directional coupler. Thus, if the coupler has poor directivity, these unwanted signals propagate to the output port and degrade the purity of the DRO output spectrum.

Thus, there is a need for a directional coupler and method therefor that exhibits improved directivity. Such a need and others are met herein in accordance with the invention.

### SUMMARY OF THE INVENTION

An aspect of the invention relates to a new and improved directional coupler and method therefor characterized in having improved directivity. The directional coupler and methodology uses enhanced destructive interference to suppress the leakage at the output port of a signal incident at the coupled port of the coupler. It has long been known that for an ideal coupler there is no signal present at the coupler's isolated port. A non-ideal coupler may have a low-level signal at this port. The design of the improved directional coupler more successfully suppresses this signal through the use of a more finely tuned destructive interference, thereby providing improved directivity. For a signal incident at the coupled port, the output port behaves as if it is the isolated port. The directional coupler of the invention creates destructive interference of a signal that is incident at the coupled port by the introduction of one or more impedance discontinuities in the coupled transmission lines. If the impedance discontinuities are properly configured, destructive interference of the signal incident at the coupled port occurs, resulting in less leakage of this signal at the output port.

More specifically, the directional coupler comprises an input port, an output port, a coupled port, an isolated port, and a pair of coupled transmission lines having a first coupling transmission line with ends respectively coupled to the input and output ports, and a second coupling transmission line with ends respectively coupled to the coupled and isolated ports. The coupled transmission lines each or both include one or more impedance discontinuities which are configured to cause further destructive interference of a signal that is incident at the coupled port, resulting in less leakage of this signal at the output port. The signal incident at the coupled port is split into two parts. The first part of the signal is propagated along one part of the coupler while the second part of the signal is propagated along the adjacent second part of the coupler. Due to the discontinuities present in the design of the coupler, these two signals are caused to have substantially equal amplitudes and substantially opposite phases. This causes the two signals to substantially interfere destructively with each other. Since the signal that is incident at the coupled port has its level reduced at the output port due to the destructive interference, the directional coupler has improved directivity. Assuming that there is little to no resistive loss in the coupler's transmission lines, the level of the signal is reduced at the output port due to substantially destructive interference. The remaining energy is reflected back from the output port and dispersed out the other ports of the coupler.

The impedance discontinuity in the coupled transmission lines can take on many forms. In one exemplary embodiment, the impedance discontinuity is a pair of recesses symmetrically positioned on respective coupling sides of the coupled transmission lines. In another embodiment, the impedance discontinuity is a pair of recesses symmetrically positioned on respective coupling sides of the coupled transmission lines, and a pair of protrusions symmetrically positioned on the non-coupling sides of the coupled transmission lines. In this exemplary embodiment, the recess and protrusion coincide positionally along the coupled transmission lines. Another embodiment may include coupled transmission lines having respective non-coupling sides that are tapered from the ends of the coupled transmission lines to the discontinuities on the lines.

Another aspect of the invention is a directional coupler that is capable of being tuned for different coupling levels. This directional coupler comprises an input port, an output port, a coupled port, an isolated port, and a pair of coupled transmission lines. One of the pair of coupled transmission lines has ends coupled respectively to the input and output ports, and the other pair has ends coupled to the coupled and isolated ports. Adjacent conducting areas are provided between the coupled transmission lines to allow higher coupling when the pair of coupled transmission lines are connected to the adjacent conducting areas. Another set of adjacent conducting areas are provided on respective non-coupling sides of the coupled transmission lines to give the coupled transmission lines the proper characteristic impedance when the coupling-side adjacent conducting areas are not connected to the coupled transmission lines.

Other aspects of the invention include a local oscillator, receiver and transmitter that use the directional couplers of the invention. Other aspects, features and techniques of the invention will become apparent to one skilled in the relevant art in view of the following detailed description of the invention.

### BRIEF DESCRIPTION OF THE DRAWINGS

FIG. 1 illustrates a top view of an exemplary directional coupler in accordance with the invention;

FIG. 2 illustrates a top view of another exemplary directional coupler in accordance with the invention;

FIG. 3 illustrates a top view of yet another exemplary directional coupler in accordance with the invention;

FIG. 4A illustrates a top view of still another exemplary directional coupler in accordance with the invention without connection to adjacent conductors;

FIG. 4B illustrates a top view of still another exemplary directional coupler in accordance with the invention with connections to adjacent conductors in a manner that provides looser coupling;

FIG. 4C illustrates a top view of still another exemplary directional coupler in accordance with the invention with connections to adjacent conductors in a manner that provides medium coupling;

FIG. 4D illustrates a top view of still another exemplary directional coupler in accordance with the invention with connections to adjacent conductors in a manner that provides tighter coupling;

FIG. 5 illustrates a block diagram of an exemplary local oscillator that includes a directional coupler in accordance with the invention;

FIG. 6 illustrates a block diagram of an exemplary receiver that includes at least one directional coupler in accordance with the invention; and

FIG. 7 illustrates a block diagram of an exemplary transmitter that includes at least one directional coupler in accordance with the invention.

### DETAILED DESCRIPTION OF THE INVENTION

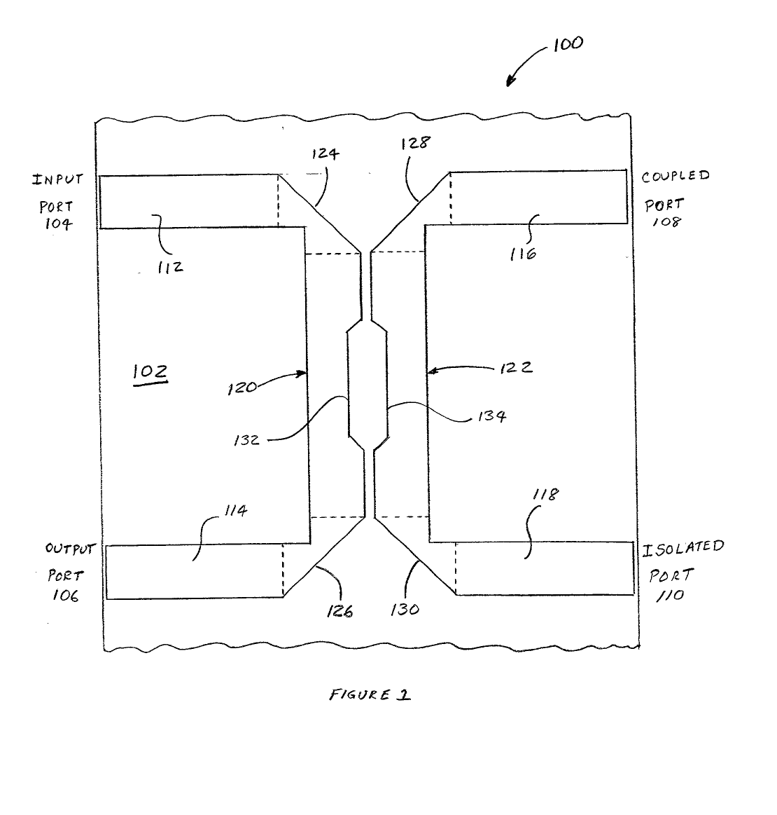

FIG. 1 illustrates a top view of an exemplary directional coupler 100 in accordance with the invention. The directional coupler 100 comprises an input port 104, an output port 106, a coupled port 108, and an isolated port 110. As with all couplers, the act of defining a port as the input port determines the function of the remaining ports. For example, if port 108 was used as the input port, the output of the coupler would be at port 110, the signal would be coupled out to port 104, and port 106 would be the isolated port. The coupler 100 further comprises a pair of coupled transmission lines 120 and 122. The directional coupler 100 may also include leading transmission lines 112, 114, 116 and 118 with corresponding 90-degree bends 124, 126, 128 and 130 which respectively couple the input port 104, output port 106, coupled port 108, and isolated port 110 to the coupled lines 120 and 122. The leading transmission lines, the 90 degree bends, and the coupled transmission lines are all formed as a continuous electrical conductive layer disposed on a substrate 102, which can be a dielectric substrate such as alumina, quartz, silicon, or gallium arsenide. Dashed lines are shown in FIG. 1 to indicate the respective boundaries between the leading transmission lines, the 90-degree bends, and the coupled transmission lines.

As previously discussed, a problem with traditional couplers is that they typically have relatively low directivity. That is, an incident signal at the coupled port typically leaks out the output port. This leakage is typically about 10 dB lower than the coupling level for the coupler. For example, if a 10-dB coupler is used, it is expected that the leaked signal at the output port is approximately 20 dB below the level of the signal incident at the coupled port. For DRO applications, this leaked signal at the output port contaminates the output spectrum of the DRO, generally requiring external filtering to better clean the DRO output. In many circumstances, the spectrum of the leaked signal from the coupled port is so close in frequency to the signal from the input port that it is not possible to filter out the unwanted spectral lines. In this case, the performance of the system is degraded and there are no means to correct the problem. Thus, there is a need for a directional coupler with higher directivity, such as about 40 dB. If such were the case, the leaked signal at the output port would be 40 dB below the level of the signal incident at the coupled port. This is a substantial reduction of the leaked signal power by about 20 dB or a factor of 100.

In order to provide this improved directivity, the directional coupler 100 includes coupled transmission lines 120 and 122 having respectively impedance discontinuities 132 and 134 that create additional destructive interference (beyond the destructive interference of this signal produced by the conventional directional coupler) of the signal incident at the coupled port 108, resulting in less leakage of this signal at the output port 106. More specifically, the discontinuities generated at the changes in line width before and after regions containing recesses 132 and 134 are designed to generate two signals that originate from the signal that is incident at the coupled port 108 (a first part and a second part) that are substantially equal in amplitude and substantially opposite in phase. Destructive interference occurs when a signal combines with another signal that is propagating in the same direction as the first signal, but cycling with opposite phase and equal amplitude. Since these two signals are substantially equal in amplitude and substantially opposite in phase, the leakage signal from the coupled port 108 is substantially reduced at the output port 106 thereby improving the directivity of the coupler 100. Since there is substantially no leakage signal from the coupled port 108 present at the output port 106, this signal power is then caused to exit out one or more of the other ports.

In the exemplary embodiment, the impedance discontinuities 132 and 134 are in a form of respective recesses on the coupling side of the coupled transmission lines 120 and 122. The recesses are generally positioned near the middle of the coupled transmission lines 120 and 122. The ends of the recesses are tapered to make a smoother transition to the non-recessed portions of the coupled transmission lines 120 and 122. The depth and length of the recesses are selected to obtain a desired directivity for the coupler 100. The recesses are generally symmetrical about the coupling axis (the axis that extends parallel to the coupled transmission lines, and is midway between the coupled transmission lines), but they need not be symmetrical.

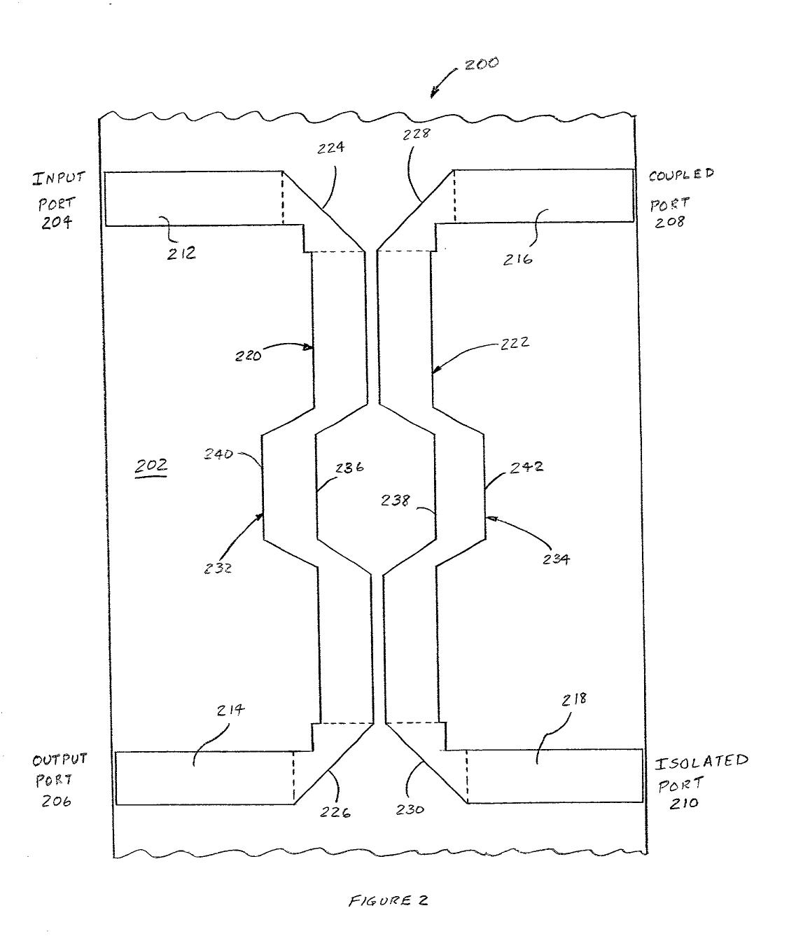

FIG. 2 illustrates a top view of another exemplary directional coupler 200 in accordance with the invention. The directional coupler 200 comprises an input port 204, an output port 206, a coupled port 208, and an isolated port 210. The coupler 200 further comprises a pair of coupled transmission lines 220 and 222. The directional coupler 200 may also include leading transmission lines 212, 214, 216 and 218 with corresponding 90-degree bends 224, 226, 228 and 230 which respectively couple the input port 204, output port 206, coupled port 208, and isolated port 210 to the coupled transmission lines 220 and 222. The leading transmission lines, the 90 degree bends, and the coupled lines are all formed as a continuous electrical conducting layer disposed on a substrate 202, which can be a dielectric substrate such as alumina, quartz, silicon, or gallium arsenide. The 90-degree bends each have an added step at the inner corner of the bends. Dashed lines are shown in FIG. 2 to indicate the respective boundaries between the leading transmission lines, the 90-degree bends, and the coupled transmission lines.

The directional coupler 200 also includes coupled transmission lines 220 and 222 having respectively impedance discontinuities 232 and 234 that create additional destructive interference of an signal incident at the coupled port 208, resulting in less leakage of this signal at the output port 206, thereby improving the coupler's directivity. In the exemplary directional coupler 200, the impedance discontinuities 232 and 234 are in a form of respective recesses 236 and 238 on the coupling side of the coupled transmission lines 220 and 222, and corresponding protrusions 240 and 242 on the non-coupling side of the transmission lines 220 and 222. The recesses 236 and 238 and protrusions 240 and 242 generally coincide along and are positioned near the middle of the coupled transmission lines 220 and 222. The ends of the recesses 236 and 238 and protrusions 240 and 242 are tapered to make a smoother transition to the non-recessed and non-protruded portions of the coupled transmission lines 220 and 222. The depth and length of the recesses 236 and 238 and corresponding protrusions 240 and 242 are selected to obtain a desired directivity for the coupler 200. The recesses and protrusions are generally symmetrical about the coupling axis, but they need not be symmetrical.

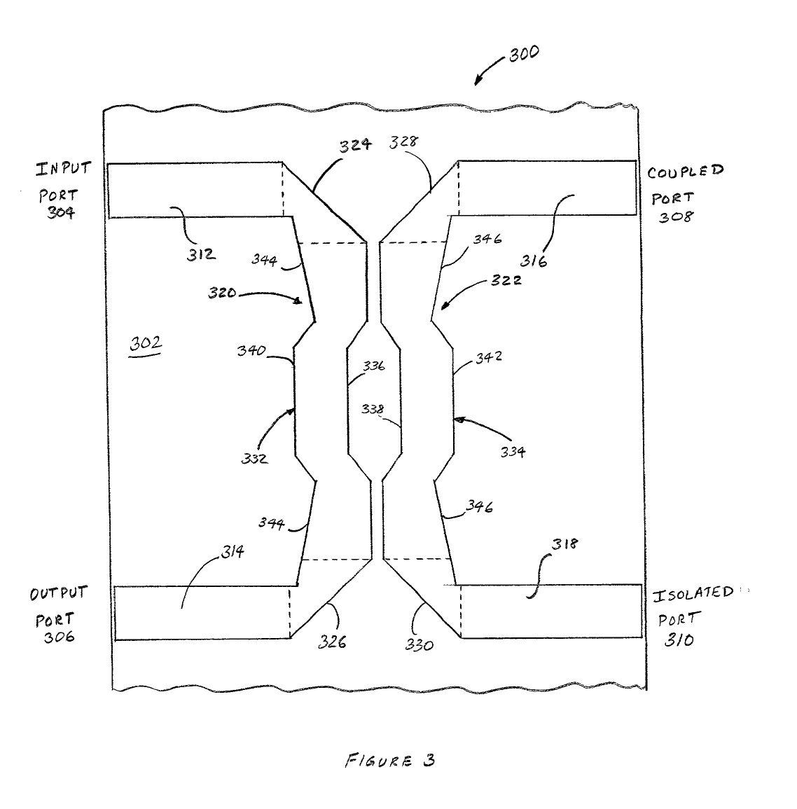

FIG. 3 illustrates a top view of yet another exemplary directional coupler 300 in accordance with the invention. The directional coupler 300 comprises an input port 304, an output port 306, a coupled port 308, and an isolated port 310. The coupler 300 further comprises a pair of coupled transmission lines 320 and 322. The directional coupler 300 may also include leading transmission lines 312, 314, 316 and 318 with corresponding 90-degree bends 324, 326, 328 and 330 which respectively couple the input port 304, output port 306, coupled port 308, and isolated port 310 to the coupled transmission lines 320 and 322. The leading transmission lines, the 90 degree bends, and the coupled lines are all formed as a continuous electrical conducting layer disposed on a substrate 302, which can be a dielectric substrate such as alumina, quartz, silicon, or gallium arsenide. Dashed lines are shown in FIG. 3 to indicate the respective boundaries between the leading transmission lines, the 90-degree bends, and the coupled transmission lines.

The directional coupler 300 also includes coupled transmission lines 320 and 322 having respectively impedance discontinuities 332 and 334 that create additional destructive interference of a signal incident at the coupled port 308, resulting in less leakage of this signal at the output port 306, thereby improving the coupler's directivity. In the exemplary directional coupler 300, the impedance discontinuities 332 and 334 are in a form of respective recesses 336 and 338 on the coupling side of the coupled transmission lines 320 and 322, and corresponding protrusions 340 and 342 on the non-coupling side of the transmission lines 320 and 322. The recesses 336 and 338 and protrusions 340 and 342 generally coincide along and are positioned near the middle of the coupled transmission lines 320 and 322. The ends of the recesses 336 and 338 and protrusions 340 and 342 are tapered to make a smoother transition to the non-recessed and non-protruded portions of the coupled transmission lines 320 and 322. The depth and length of the recesses 336 and 338 and corresponding protrusions 340 and 342 are selected to obtain a desired directivity for the coupler 300. The recesses and protrusions are generally symmetrical about the coupling axis, but they need not be symmetrical.

Directional coupler 300 differs from coupler 200 in that the non-coupling sides of the coupled transmission lines 320 and 322 is respectively tapered 344 and 346 as they extend from their respective 90-degree bends 324, 326, 328 and 330 to the impedance discontinuities 332 and 334. Also, the inner corners of the 90-degree bends 324, 326, 328 and 330 do not include steps, but are part of tapered transitions 344 and 346. The tapered transitions 344 and 346 improve the impedance match of the coupler 300.

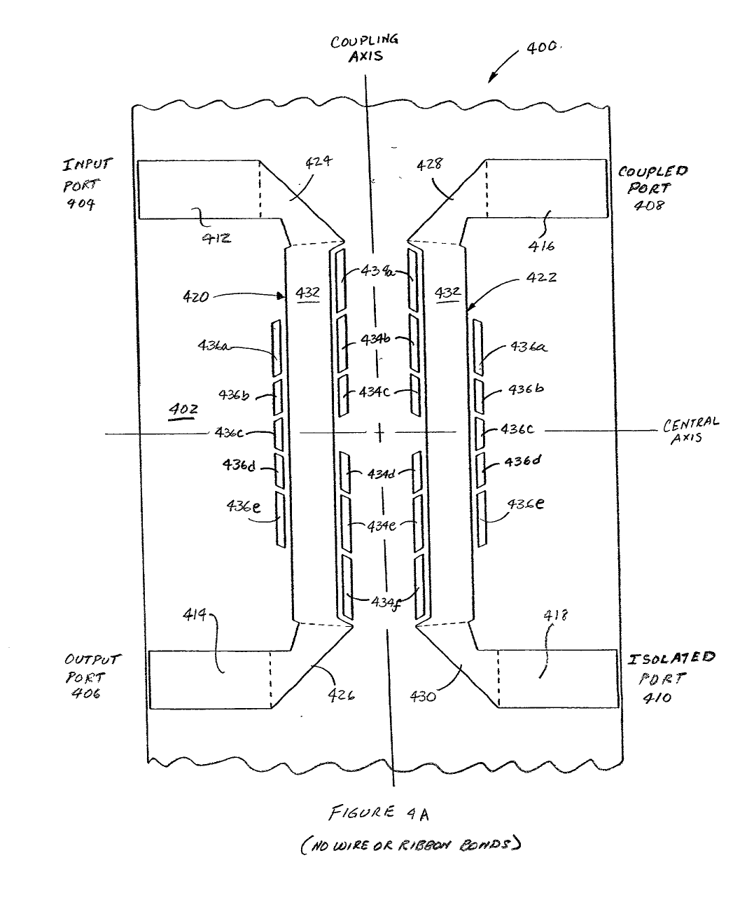

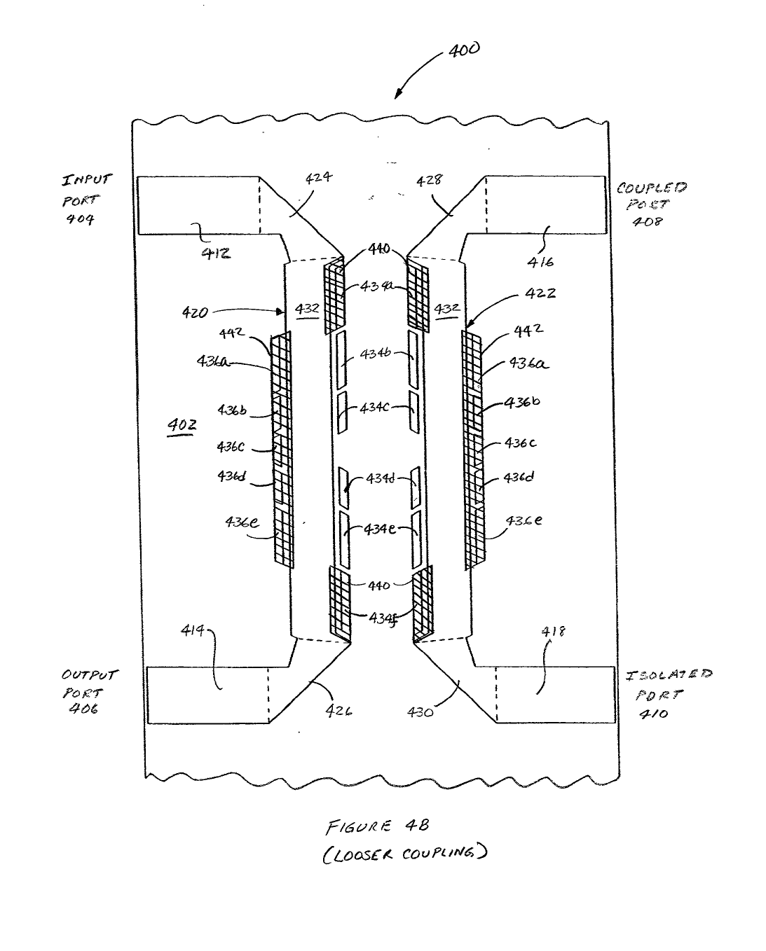

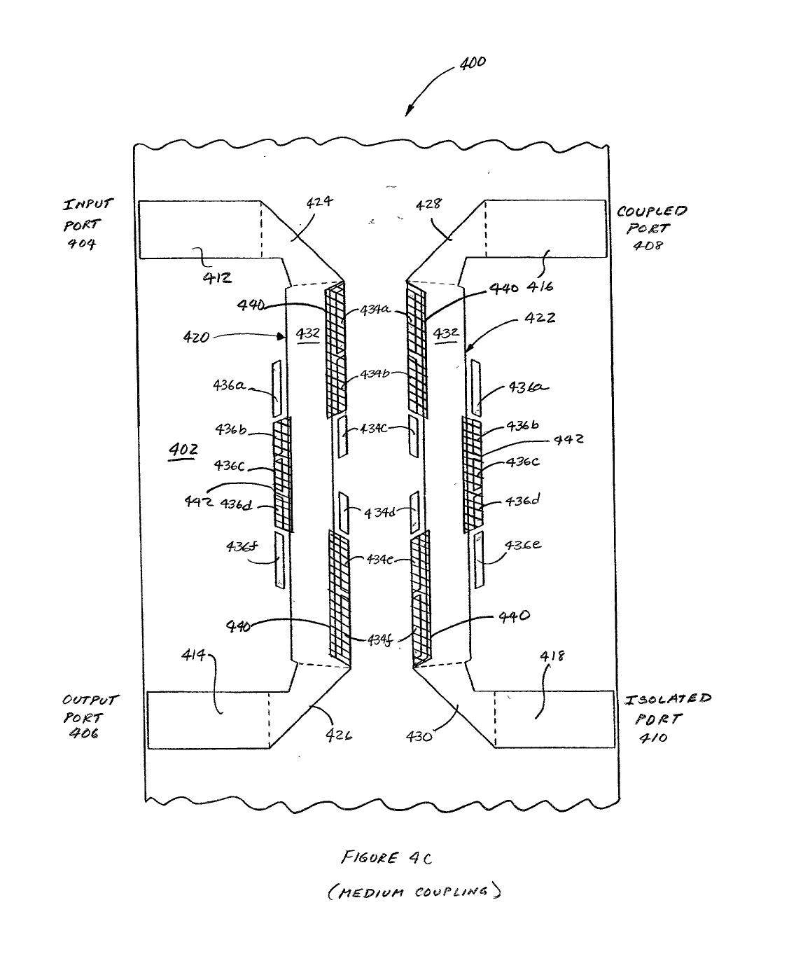

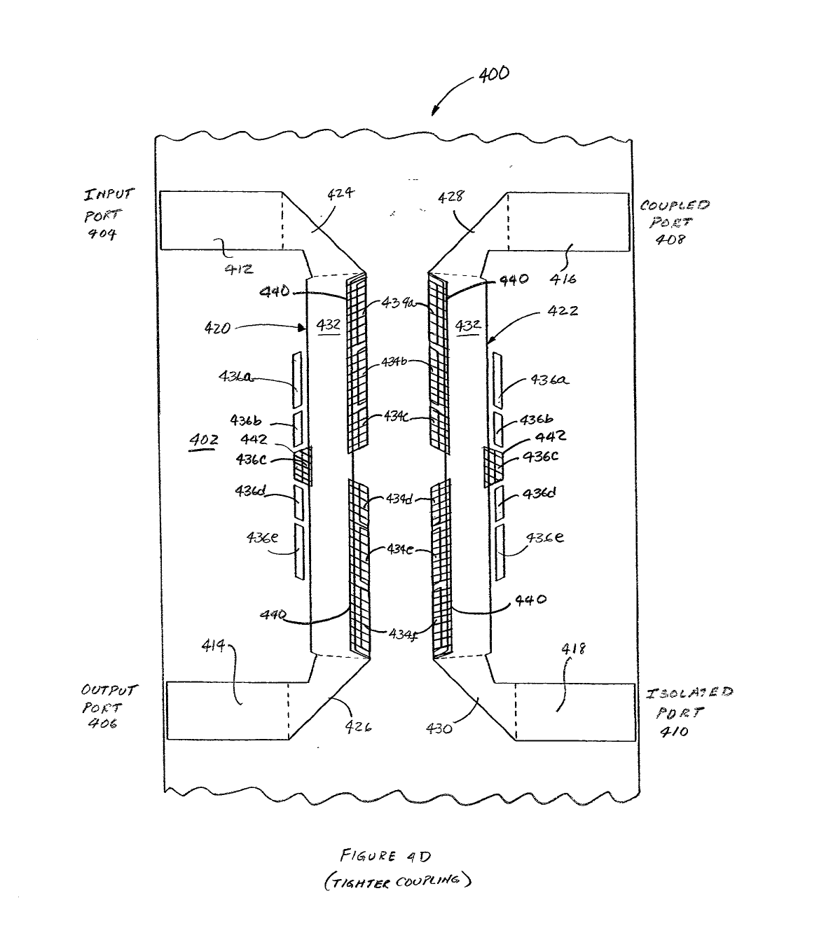

FIG. 4A illustrates a top view of still another exemplary directional coupler 400 in accordance with the invention without connection to adjacent conductors. Directional coupler 400 facilitates tuning of the coupler to provide different coupling levels. This feature is particularly useful for prototyping with directional couplers. The directional coupler 400 comprises input port 404, output port 406, coupled port 408, and isolated port 410. The coupler 400 further comprises a pair of coupled transmission lines 420 and 422. The directional coupler 400 may also include leading transmission lines 412, 414, 416 and 418 with corresponding 90-degree bends 424, 426, 428 and 430 which respectively couple the input port 404, output port 406, coupled port 408, and isolated port 410 to the coupled transmission lines 420 and 422. The leading transmission lines, the 90 degree bends, and the coupled transmission lines are all formed as a continuous electrical conducting layer disposed on a substrate 402, which can be a dielectric substrate such as alumina, quartz, silicon, or gallium arsenide. Dashed lines are shown in FIG. 4 to indicate the respective boundaries between the leading transmission lines, the 90-degree bends, and the coupled transmission lines.

To give the directional coupler 400 coupling level tuning capability, the coupled transmission lines 420 and 422 each comprises a primary transmission line 432, one or more adjacent conductors 434a-f on the coupling side of the primary transmission line 432, and one or more adjacent conductors 436a-e on the non-coupling side of the primary transmission line 432. In the exemplary embodiment, the adjacent conductors 434a-f and 436a-e extend generally parallel with and are spaced apart from the primary transmission line 432. Also, they are symmetrical about a central and coupling axes of the coupler 400. Without wire or ribbon bonds connecting the primary transmission line 432 to the adjacent conductors 434a-f and 436a-e, the adjacent conductors 434a-f and 436a-f are substantially signal isolated from the line 432. Once they are fully connected to the primary transmission line 432 by one or more ribbon or wire bonds, they are then signally coupled to the line 432.

FIG. 4B illustrates a top view of the exemplary directional coupler 400 in accordance with the invention with connections to adjacent conductors in a manner that provides looser coupling. For looser coupling, the adjacent conductors 434a and 434f on the coupling-side are respectively electrically connected to the corresponding primary transmission lines 432 by one or more wire or ribbon bonds 440, and the adjacent conductors 436a-e on the non-coupling side are respectively electrically connected to the corresponding primary transmission lines 432 by one or more ribbon bonds 442. Looser coupling is achieved because only a relatively small portion (i.e. the combined lengths of adjacent conductors 434a and 434f) of the total coupling length is coupled closer due to the bridging of the primary transmission lines 432 to the corresponding adjacent conductors 434a and 434f.

The electrical connection of the primary transmission lines 432 to the corresponding adjacent coupling-side conductors 434a and 434f gives the coupled transmission lines 420 and 422 a particular width at that region, which translates to a particular characteristic impedance. In order to maintain substantially the same characteristic impedance for the coupled transmission lines 420 and 422 throughout their lengths, the primary transmission lines 432 are electrically connected to the adjacent non-coupling conductors 436a-e at the portions of the coupled transmission lines 420 and 422 where there is no bridging of the primary transmission lines 432 to the corresponding adjacent coupling-side conductors 434a and 434f. In this manner, the widths of the coupled transmission lines 420 and 422 are substantially constant throughout their lengths, thereby maintaining substantially the same characteristic impedance throughout the lengths of the coupled transmission lines 420 and 422.

FIG. 4C illustrates a top view of the exemplary directional coupler 400 in accordance with the invention with connections to adjacent conductors in a manner that provides medium coupling. For medium coupling, the adjacent conductors 434a-b and 434e-f on the coupling-side are respectively electrically connected to the corresponding primary transmission lines 432 by one or more wire or ribbon bonds 440, and the adjacent conductors 436b-d on the non-coupling side are respectively electrically connected to the corresponding primary transmission lines 432 by one or more ribbon bonds 442. Medium coupling is achieved because about half (i.e. the combined lengths of adjacent conductors 434a-b and 434e-f) of the total coupling length is coupled closer due to the bridging of the primary transmission lines 432 to the corresponding adjacent conductors 434a-b and 434e-f. In order to maintain substantially the same characteristic impedance for the coupled transmission lines 420 and 422 throughout their lengths, the primary transmission lines 432 are electrically connected to the adjacent non-coupling conductors 436b-c at the portions of the coupled transmission lines 420 and 422 where there is no bridging of the primary transmission lines 432 to the corresponding adjacent coupling-side conductors 434a-b and 434e-f.

FIG. 4D illustrates a top view of the exemplary directional coupler 400 in accordance with the invention with connections to adjacent conductors in a manner that provides tighter coupling. For tighter coupling, the adjacent conductors 434a-f on the coupling-side are respectively electrically connected to the corresponding primary transmission lines 432 by one or more wire or ribbon bonds 440, and the adjacent conductors 436c on the non-coupling side are respectively electrically connected to the corresponding primary transmission lines 432 by one or more ribbon bonds 442. Tighter coupling is achieved because a major portion (i.e. the combined lengths of adjacent conductors 434a-f) of the total coupling length is coupled closer due to the bridging of the primary transmission lines 432 to the corresponding adjacent conductors 434a-f. In order to maintain substantially the same characteristic impedance for the coupled transmission lines 420 and 422 throughout their lengths, the primary transmission lines 432 are electrically connected to the adjacent non-coupling conductors 436c at the portions of the coupled transmission lines 420 and 422 where there is no bridging of the primary transmission lines 432 to the corresponding adjacent coupling-side conductors 434a-f.

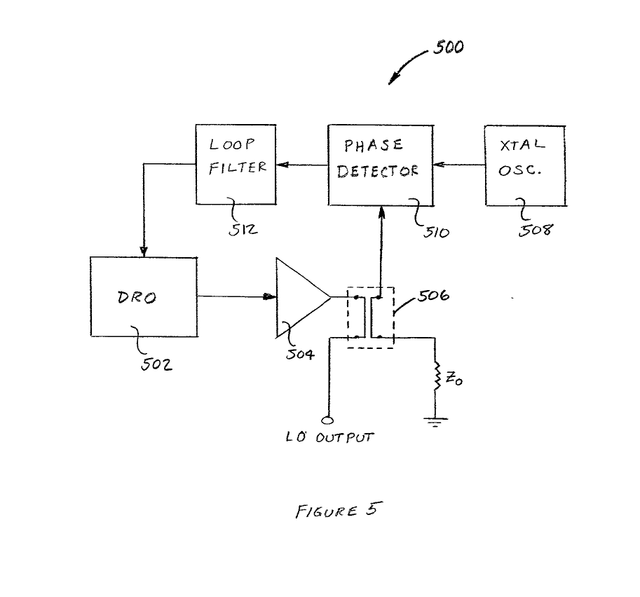

FIG. 5 illustrates a block diagram of an exemplary local oscillator 500 using a directional coupler in accordance with the invention. The local oscillator 500 comprises a DRO 502 (which can also be any type of tunable RF/microwave/millimeterwave oscillator), an amplifier 504 (or other device that isolates the output of the DRO 502 from the load connected to the LO output port, such as an attenuator or isolator), a directional coupler 506 (e.g. directional couplers 100, 200, 300 or 400), a crystal oscillator 508, a phase detector 510, and a loop filter 512. The coupler's input port is coupled to the output of the amplifier 504, the coupled port is coupled to the phase detector 510, the isolated port is coupled to a load impedance of Z₀, and the output port serves as the output of the local oscillator 500.

The DRO 502 generates a relatively low phase noise LO signal, which is amplified by amplifier 504. A portion of the amplified LO signal is coupled to the phase detector 510 by the coupler 506. The phase detector 510 compares the phase of the reference signal from the crystal oscillator 508 to the phase of the sampled LO signal, and generates a phase error signal. The phase error signal is applied to the loop filter 512 to filter out unwanted frequency components so as to generate the tuning voltage V_{TUNE} for the DRO 502 to maintain the DRO output within a frequency specification.

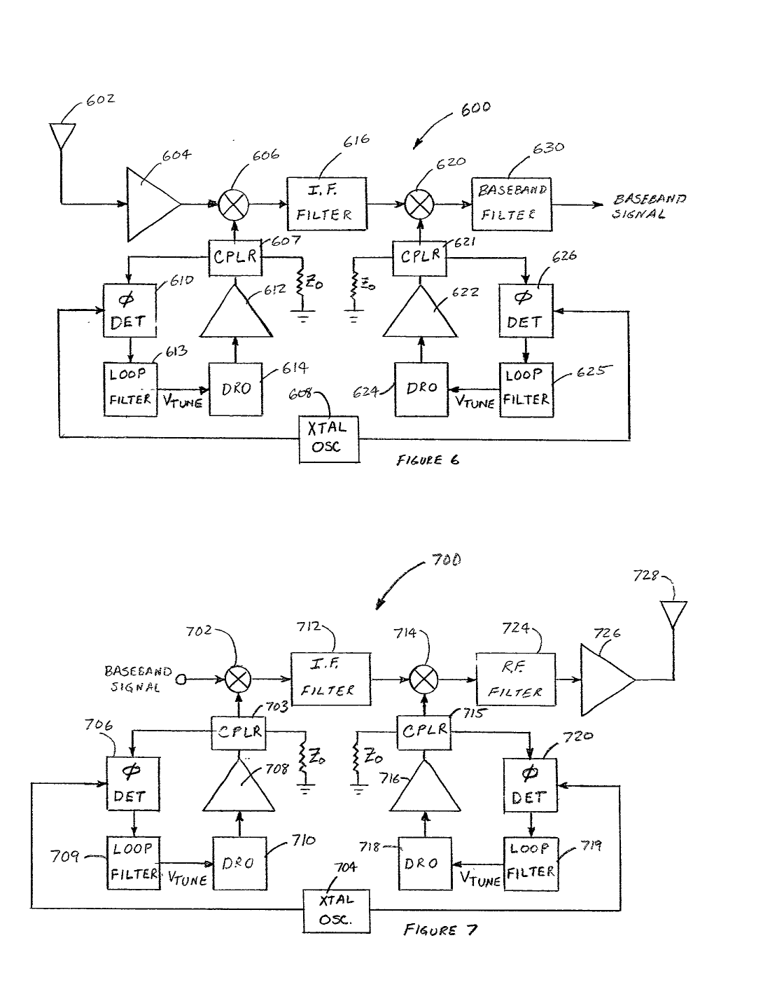

FIG. 6 illustrates a block diagram of an exemplary receiver 600 using a directional coupler in accordance with the invention. The directional couplers of the invention can be used in many applications, even as part of the receiver 600. The receiver 600 comprises a low noise amplifier 604 having an input for receiving an RF/microwave/millimeterwave signal from an antenna 602 or other transmission source. The output of the low noise amplifier 604 is coupled to a first down-converting stage comprising a first mixer 606 and a first local oscillator (LO) comprising DRO 614, optional amplifier 612 (or other device that isolates the output of the DRO 614 from the mixer 606, such as an attenuator or isolator), a directional coupler 607 (e.g. couplers 100, 200, 300 and 400), phase detector 610, a reference crystal oscillator 608, and a loop filter 613. The output of the DRO 614 is optionally coupled to the input of the amplifier 612 for isolating the output of the DRO 614. A portion of the local oscillator signal at the output of the amplifier 612 is coupled to the phase detector 610 to phase compare the local oscillator signal with the reference from the crystal oscillator 608, and to generate a phase error signal. The phase error signal is applied to the loop filter 613 to generate a tuning voltage V_{TUNE} for the DRO 614 to keep the DRO output within a frequency specification.

The output of the mixer 606 is coupled to an intermediate frequency (IF) filter 616 to remove the higher frequency products and other unwanted signals from the down-converted received signal. If two-stage down-conversion is desired, the output of the IF filter 616 is coupled to a second down-converting stage comprising a second mixer 620 and a second local oscillator (LO) comprising DRO 624, optional amplifier 622 (or other device that isolates the output of the DRO 624 from the mixer 620, such as an attenuator or isolator), a directional coupler 621 (e.g. couplers 100, 200, 300 and 400), a phase detector 626, the reference crystal oscillator 608 (being common to both down-converting stages), and a loop filter 625. The output of the DRO 624 is optionally coupled to the input of the amplifier 622 for isolating the output of the DRO 624. A portion of the local oscillator signal at the output of the amplifier 622 is coupled to the phase detector 626 to phase compare the local oscillator signal with the reference from the crystal oscillator 608, and to generate a phase error signal. The phase error signal is applied to the loop filter 625 to generate the tuning voltage V_{TUNE} for the DRO 624 to keep the DRO output within a frequency specification. The output of the mixer 620 is coupled to a baseband filter 630 to remove the higher frequency products and other unwanted signals from the second down-converted received signal to generate a baseband signal.

FIG. 7 illustrates a block diagram of an exemplary transmitter 700 using a directional coupler in accordance with the invention. The directional couplers of the invention can be used in many applications, even as part of the transmitter 700. The transmitter 700 comprises a first up-converting stage for up-converting a baseband signal. The first up-converting stage comprises a first mixer 702 and a first local oscillator (LO) comprising DRO 710, optional amplifier 708 (or other device that isolates the output of the DRO 710 from the mixer 702, such as an attenuator or isolator), a directional coupler 703 (e.g. couplers 100, 200, 300 and 400), phase detector 706, a reference crystal oscillator 704, and a loop filter 709. The output of the DRO 710 is optionally coupled to the input of the amplifier 708 for isolating the output of the DRO 710. A portion of the local oscillator signal at the output of the amplifier 708 is coupled to the phase detector 706 to phase compare the local oscillator signal with the reference from the crystal oscillator 704, and to generate a phase error signal. The phase error signal is applied to the loop filter 709 to generate a tuning voltage VTUNE for the DRO 710 to keep the DRO output within a frequency specification.

The output of the mixer 702 is coupled to an intermediate frequency (IF) filter 712 to remove the lower frequency products and other unwanted signals from the up-converted signal. If two-stage up-conversion is desired, the output of the IF filter 712 is coupled to a second up-converting stage comprising a second mixer 714 and a second local oscillator (LO) comprising DRO 718, optional amplifier 716, a directional coupler 715 (e.g. couplers 100, 200, 300 and 400), phase detector 720, the reference crystal oscillator 704 (being common to both up-converting stages), and a loop filter 719. The output of the DRO 718 is coupled to the input of the amplifier 716 for increasing the power of the local oscillator signal sufficiently to drive the mixer 714. A portion of the local oscillator signal at the output of the amplifier 716 is coupled to the phase detector 720 to phase compare the local oscillator signal with the reference from the crystal oscillator 704, and to generate a phase error signal. The phase error signal is applied to the loop filter 719 to generate a tuning voltage V_{TUNE} for the DRO 718 to keep the DRO output within a frequency specification.

The output of the mixer 714 is coupled to a radio frequency (RF)/microwave/millimeterwave filter 724 to remove the lower frequency products and other unwanted signals from the second up-converted signal to generate the RF/microwave/millimeterwave signal for transmission via a wireless medium or other transmission medium. The output of the RF/microwave/millimeterwave filter 724 is coupled to the input of a power amplifier 726 (which can comprise of one or more amplification stages) for increasing the power of the RF/microwave/millimeterwave signal for transmission over the wire medium via the antenna 728 or transmission over other types of transmission mediums.

In the foregoing specification, the invention has been described with reference to specific embodiments thereof. It will, however, be evident that various modifications and changes may be made thereto departing from the broader spirit and scope of the invention. The specification and drawings are, accordingly, to be regarded in an illustrative rather than a restrictive sense.

### Appendix A

I hereby appoint BLAKELY, SOKOLOFF, TAYLOR & ZAFMAN LLP, a firm including: William E. Alford, Reg. No. 37,764; Farzad E. Amini, Reg. No. 42,261; William Thomas Babbitt, Reg. No. 39,591; Carol F. Barry, Reg. No. 41,600; Jordan Michael Becker, Reg. No. 39,602; Lisa N. Benado, Reg. No. 39,995; Bradley J. Bereznak, Reg. No. 33,474; Michael A. Bernadicou, Reg. No. 35,934; Roger W. Blakely, Jr., Reg. No. 25,831; R. Alan Burnett, Reg. No. 46,149; Gregory D. Caldwell, Reg. No. 39,926; Andrew C. Chen, Reg. No. 43,544; Thomas M. Coester, Reg. No. 39,637; Donna Jo Coningsby, Reg. No. 41,684; Dennis M. deGuzman, Reg. No. 41,702; Justin Dillon, Reg. No. 42,486; Stephen M. De Klerk, Reg. No. P46,503; Michael Anthony DeSanctis, Reg. No. 39,957; Daniel M. De Vos, Reg. No. 37,813; Sanjeet Dutta, Reg. No. P46,145; Matthew C. Fagan, Reg. No. 37,542; Tarek N. Fahmi, Reg. No. 41,402; George Fountain, Reg. No. 36,374; Paramita Ghosh, Reg. No. 42,806; James Y. Go, Reg. No. 40,621; James A. Henry, Reg. No. 41,064; Willmore F. Holbrow III, Reg. No. P41,845; Sheryl Sue Holloway, Reg. No. 37,850; George W Hoover II, Reg. No. 32,992; Eric S. Hyman, Reg. No. 30,139; William W. Kidd, Reg. No. 31,772; Sang Hui Kim, Reg. No. 40,450; Walter T. Kim, Reg. No. 42,731; Eric T. King, Reg. No. 44,188; Erica W. Kuo, Reg. No. 42,775; George B. Leavell, Reg. No. 45,436; Gordon R. Lindeen III, Reg. No. 33,192; Jan Carol Little, Reg. No. 41,181; Robert G. Litts, Reg. No. 46,876; Kurt P. Leyendecker, Reg. No. 42,799; Joseph Lutz, Reg. No. 43,765; Michael J. Mallie, Reg. No. 36,591; Andre L. Marais, under 37 C.F.R. § 10.9(b); Paul A. Mendonsa, Reg. No. 42,879; Clive D. Menezes, Reg. No. 45,493; Chun M. Ng, Reg. No. 36,878; Thien T. Nguyen, Reg. No. 43,835; Thinh V. Nguyen, Reg. No. 42,034; Dennis A. Nicholls, Reg. No. 42,036; Daniel E. Ovanezian, Reg. No. 41,236; Kenneth B. Paley, Reg. No. 38,989; Marina Portnova, Reg. No. P45,750; William F. Ryann, Reg. 44,313; James H. Salter, Reg. No. 35,668; William W. Schaal, Reg. No. 39,018; James C. Scheller, Reg. No. 31,195; Jeffrey S. Schubert, Reg. No. 43,098; George Simion, Reg. No. P-47,089; Jeffrey Sam Smith, Reg. No. 39,377; Maria McCormack Sobrino, Reg. No. 31,639; Stanley W. Sokoloff, Reg. No. 25,128; Judith A. Szepesi, Reg. No. 39,393; Vincent P. Tassinari, Reg. No. 42,179; Edwin H. Taylor, Reg. No. 25,129; John F. Travis, Reg. No. 43,203; Joseph A. Twarowski, Reg. No. 42,191; Mark C. Van Ness, Reg. No. 39,865; Thomas A. Van Zandt, Reg. No. 43,219; Lester J. Vincent, Reg. No. 31,460; Glenn E. Von Tersch, Reg. No. 41,364; John Patrick Ward, Reg. No. 40,216; Mark L. Watson, Reg. No. P46,322; Thomas C. Webster, Reg. No. P46,154; and Norman Zafman, Reg. No. 26,250; my patent attorneys, and Firasat Ali, Reg. No. 45,715; and Justin M. Dillon, Reg. No. 42,486; Raul Martinez, Reg. No. 46,904; my patent agents, with offices located at 12400 Wilshire Boulevard, 7th Floor, Los Angeles, Calif. 90025, telephone (714) 557-3800, with full power of substitution and revocation, to prosecute this application and to transact all business in the Patent and Trademark Office connected herewith.

What is claimed is:

1. A directional coupler, comprising:
an input port;
an output port;
a coupled port;
an isolated port; and
a pair of coupled transmission lines one of which has ends coupled respectively to said input and output ports, the other has ends respectively coupled to said coupled and isolated ports, wherein said first and/or second coupled transmission lines further includes an impedance discontinuity configured to improve said directivity of said directional coupler.

2. The directional coupler of claim 1, wherein said impedance discontinuity is in a form of a recess at a portion of said first and/or second coupled transmission line.

3. The directional coupler of claim 2, wherein said recess is on a coupling side of said first and/or second coupled transmission line.

4. The directional coupler of claim 1, wherein said impedance discontinuity is in a form of a protrusion at a portion of said first and/or second coupled transmission line.

5. The directional coupler of claim 4, wherein said protrusion is on a non-coupling side of said first and/or second coupled transmission line.

6. The directional coupler of claim 1, wherein said impedance discontinuity is in a form of a recess at a portion of a coupling side of said first and/or second coupled transmission line, and a protrusion at a portion of a non-coupling side of said first and/or second coupled transmission line.

7. The directional coupler of claim 6, wherein said recess and said protrusion coincides along said first and/or second coupled transmission line.

8. The directional coupler of claim 1, wherein a side of said first and/or second coupled transmission line is tapered from said ends of said first and/or second coupled transmission line to said impedance discontinuity.

9. The directional coupler of claim 1, wherein said impedance discontinuity comprises a first discontinuity on said first coupled transmission line and a second discontinuity on said second coupled transmission line.

10. The directional coupler of claim 9, wherein said first and second discontinuities are configured symmetrically about a coupling axis.

11. A method of improving a directivity of a directional coupler, comprising introducing an impedance discontinuity to either or both coupled transmission lines of said coupler to cause destructive interference of a signal incident at a coupled port of said directional coupler.

12. The method of claim 11, wherein introducing said impedance discontinuity comprises introducing a recess at a portion of said first and/or second coupled transmission line.

13. The method of claim 12, wherein introducing said recess comprises introducing said recess on a coupling side of said first and/or second coupled transmission line.

14. The method of claim 11, wherein introducing said impedance discontinuity comprises introducing a protrusion at a portion of said first and/or second coupled transmission line.

15. The method of claim 14, wherein introducing said protrusion comprises introducing said protrusion on a non-coupling side of said first and/or second coupled transmission line.

16. The method of claim 11, wherein introducing said impedance discontinuity comprises:
introducing a recess at a portion of a coupling side of said first and/or second coupled transmission line; and
introducing a protrusion at a portion of a non-coupling side of said first and/or second coupled transmission line.

17. The method of claim 16, wherein introducing said recess and said protrusion comprises positioning said recess and protrusion such that they coincide along said first and/or second transmission line.

18. The method of claim 11, further including tapering a side of said first and/or second transmission line from said ends of said first and/or second coupled transmission line to said impedance discontinuity.

19. The method of claim 11, wherein introducing said impedance discontinuity comprises:
introducing a first discontinuity on said first coupled transmission line; and
introducing a second discontinuity on said second coupled transmission line.

20. The method of claim 19, wherein introducing said first and second discontinuities is performed in a manner that said first and second discontinuities are symmetrical about a coupling axis.

21. A local oscillator, comprising:
an oscillator to generate a signal;
a reference oscillator to generate a reference signal;
a phase comparator to generate a phase error signal indicative of a phase difference between said signal and said reference signal;
a loop filter to generate a frequency tuning signal for said oscillator by filtering said phase error signal; and
a directional coupler to couple said signal to said phase comparator, said coupler comprising:
an input port;
an output port;
a coupled port;
an isolated port; and
a pair of coupled transmission lines one of which has ends coupled respectively to said input and output ports, and the other has ends respectively coupled to said coupled and isolated ports, wherein said first and/or second coupled transmission lines further includes an impedance discontinuity configured to improve said directivity of said directional coupler.

22. The local oscillator of claim 21, wherein said impedance discontinuity is in a form of a recess at a portion of said first and/or second coupled transmission line.

23. The local oscillator of claim 22, wherein said recess is on a coupling side of said first and/or second coupled transmission line.

24. The local oscillator of claim 21, wherein said impedance discontinuity is in a form of a protrusion at a portion of said first and/or second coupled transmission line.

25. The local oscillator of claim 24, wherein said protrusion is on a non-coupling side of said first and/or second coupled transmission line.

26. The local oscillator of claim 21, wherein said impedance discontinuity is in a form of a recess at a portion of a coupling side of said first and/or second coupled transmission line, and a protrusion at a portion of a non-coupling side of said first and/or second coupled transmission line.

27. The local oscillator of claim 26, wherein said recess and said protrusion coincides along said first and/or second coupled transmission line.

28. The local oscillator of claim 21, wherein a side of said first and/or second transmission line is tapered from said ends of said first and/or second transmission line to said impedance discontinuity.

29. The local oscillator of claim 21, wherein said impedance discontinuity comprises a first discontinuity on said first coupled transmission line and a second discontinuity on said second coupled transmission line.

30. The local oscillator of claim 29, wherein said first and second discontinuities are configured symmetrically about a coupling axis.

31. The local oscillator of claim 21, wherein said oscillator comprises a dielectric resonator oscillator (DRO).

32. The local oscillator of claim 21, wherein said reference oscillator comprises a crystal oscillator.

33. A directional coupler, comprising:
an input port;
an output port;
a coupled port;
an isolated port;
first and second coupled transmission lines, wherein said first coupled transmission line comprises a first primary transmission line having ends coupled respectively to said input and output ports, and said second coupled transmission line comprises a second primary transmission line having ends coupled respectively to said coupled and isolated ports;
at least one adjacent coupling-side conductor situated at a coupling side of either of said first or second primary transmission lines, wherein a coupling level between said input and coupled ports is increased when either of said first or second primary transmission line is electrically coupled to said at least one adjacent coupling-side conductor; and
at least one adjacent non-coupling-side conductor situated at a non-coupling side of either of said first or second primary transmission line, wherein a characteristic impedance is more uniform throughout either of said first or second primary transmission line when said at least one adjacent non-coupling-side conductor is electrically connected to said first or second primary transmission line.

34. A receiver or transmitter comprising at least one directional coupler as defined in claim 1.

35. A receiver or transmitter comprising at least one directional coupler as defined in claim 33.
